(19) United States
(12) Patent Application Publication
(10) Pub. No.: US 2016/0258991 A1
(43) Pub. Date: Sep. 8, 2016

(54) Method and System of Signal Processing for Phase-Amplitude Coupling and Amplitude-Amplitude coupling

(71) Applicant: HANGZHOU SHEKEDI BIOTECH CO., LTD, Hangzhou City (CN)

(72) Inventors: Kun HU, Hangzhou City (CN); Chien-Hung YEH, Taoyuan City (TW); Men-Tzung LO, Taoyuan City (TW)

(21) Appl. No.: 14/635,268

(22) Filed: Mar. 2, 2015

(51) Int. Cl. G01R 25/00; G06F 17/14; G01R 23/00

(52) U.S. Cl. CPC G01R 25/00; G01R 23/00; G06F 17/14

(57) ABSTRACT

A method implemented in a system of signal processing for phase-amplitude coupling (PAC) and amplitude-amplitude coupling (AAC), wherein comprises: decomposing a non-stationary signal by an ensemble empirical mode decomposition (EEMD) into a plurality of intrinsic mode functions (IMFs), receiving a phase function and an amplitude function from the IMFs, then comparing the phase function with the amplitude function on a time domain to generate a plurality of scattering plots. Further more, multiplying the scattering plots by the modulation index to generate a frequency spectrum. The following information will be illustrated the different part of PAC and AAC.

### FIELD OF THE INVENTION

The invention relates to a method and system of a non-stationary signal processing to generate a meaningful quantification value.

### BACKGROUND OF THE INVENTION

Previously, analyzing signals, particularly those having nonlinear and/or non-stationary properties, was a difficult problem confronting many industries. These industries have harnessed various computer implemented methods to process data signals measured or otherwise taken from various processes such as electrical, mechanical, optical, biological, and chemical processes. Unfortunately, previous methods have not yielded results which are physically meaningful. Among the difficulties found in conventional systems is that representing physical processes with physical signals may present one or more of the following problems such as the total data span is too short, the data are non-stationary and the data represent nonlinear processes.

A variety of techniques have been applied to nonlinear, non-stationary physical signals. For example, many computer implemented methods apply Fourier transform to examine the energy-frequency distribution of such signals.

Although the Fourier transform that is applied by these computer implemented methods is valid under extremely general conditions, there are some crucial restrictions: the system must be linear, and the data must be strictly periodic or stationary. If these conditions are not met, then the resulting spectrum will not make sense physically.

For example, many recorded physical signals are of finite duration, non-stationary, and nonlinear because they are derived from physical processes that are nonlinear either intrinsically or through interactions with imperfect probes or numerical schemes. Under these conditions, computer implemented methods which apply Fourier transform are of limited use. For lack of alternatives, however, such methods still apply Fourier transform to process such data.

In summary, the indiscriminate use of Fourier transform in these methods and the adoption of the stationary and linearity assumptions may give inaccurate results.

### SUMMARY OF THE INVENTION

It is an object of the present invention to overcome disadvantages for applying Fourier transform to give inaccurate results and discloses a system and method for analysis of intrinsic mode functions (IMFs) which provides a frequency spectrum based on a phase function of IMFs and an amplitude function of IMFs. The frequency spectrum provides more reliable and accurate results than the indiscriminate use Fourier transform to process analysis signals.

Briefly described, one embodiment, among others, is a method implemented in a system for signal processing for phase-amplitude coupling. The method comprises first step, receiving a non-stationary signal with amplitude and frequency changes over time. Second step, the non-stationary signal is decomposed by an ensemble empirical mode decomposition (EEMD) into a plurality of intrinsic mode functions, wherein each of the IMFs is an expression of one banded frequency component in the non-stationary signal, and each banded frequency component corresponds to one of the IMFs. Third step, a first IMF with a region of interest is selected, retrieving a phase function of the first IMF, and obtains a plurality of first cycle frequencies, wherein each first-IMF cycle frequency corresponds to the increment of the phase function across the cycle. Fourth step, a second IMF is selected, retrieving an amplitude function of the second IMFs, and obtains a plurality of second-IMF cycle frequencies, wherein each second-IMF cycle frequency corresponds to the variation of the second IMF. Fifth step, the phase function is compared with the amplitude function on a time domain to generate a scattering plot, wherein the scattering plot is based on the first cycle frequencies corresponding to the second cycle frequencies. The method further comprises repeating fourth step to fifth step, until generate the scattering plots by comparing the phase function of the first IMF with the amplitude function of each another IMF.

Another embodiment is a method for amplitude-amplitude coupling. The method comprises first step, a non-stationary signal with amplitude is received and frequency changes over time. Second step, the non-stationary signal is decomposed by an ensemble empirical mode decomposition (EEMD) into a plurality of intrinsic mode functions (IMFs), wherein each of the IMFs is an expression of one banded frequency component in the non-stationary signal, and each banded frequency component corresponds to one of the IMFs. Third step, a first IMF with a region of interest is decomposed by the EEMD into a plurality of envelop functions, wherein each of the envelop functions is an expression of one envelope frequency in the first IMF, and each envelope frequency corresponds to one of the envelop functions. Fourth step, a first envelop function is selected from the envelop functions, retrieving a phase function of the first envelop function, obtaining a plurality of first-IMF envelope cycle frequencies, wherein each first-IMF envelope cycle frequency corresponds to the variation between cycles of the first IMF. Fifth step, a second IMF is selected from the IMFs at the frequency higher than the first IMF, retrieving an amplitude function of the second IMFs, and obtaining a plurality of second-IMF cycle frequencies, wherein each second-IMF cycle frequency corresponds to the variation of the second IMF. Sixth step, the phase function is compared with the amplitude function on a time domain to generate a scattering plot, wherein the scattering plot is based on the first-IMF envelope cycle frequencies corresponding to the second-IMF cycle frequencies. Finally in seventh step, fifth step to sixth step is repeated, until generate the scattering plots by comparing the phase function of the first envelop function with the amplitude function of each another IMF at the frequency higher than the first IMF.

The present invention also provides a system of signal processing for phase-amplitude coupling. The system comprises a signal collecting unit, a signal processing unit, a signal outputting unit, and a signal comparison.

The signal collecting unit receives a non-stationary signal with amplitude and frequency changes over time.

The signal processing unit is connected to the signal collecting unit, decomposing the non-stationary signal by an ensemble empirical mode decomposition (EEMD) into a plurality of intrinsic mode functions (IMFs), wherein each of the IMFs is an expression of one banded frequency component in the non-stationary signal, and each banded frequency component corresponds to one of the IMFs.

The phase function processing unit is connected to the signal processing unit, selecting a first IMF with a region of interest, retrieving a phase function of the first IMF, and obtaining a plurality of first cycle frequencies, wherein each first cycle frequency corresponds to the increment of the phase function across the cycle.

The amplitude function processing unit is connected to the phase function processing unit, selecting a second IMF, retrieving an amplitude function of the second IMFs, and obtaining a plurality of second-IMF cycle frequencies according to the variation between of the amplitude function.

The signal comparison unit is connected to the amplitude function processing unit, comparing the phase function with the amplitude function on a time domain, generating a scattering plot according to the first-IMF cycle frequencies corresponding to the second-IMF cycle frequencies, wherein the system repeats signal processing from the amplitude function processing unit to signal comparison unit until generate the scattering plots by comparing the phase function of the first IMF with the amplitude function of each another IMF.

Another embodiment is a system of signal processing for amplitude-amplitude coupling. The system comprises a signal collecting unit, a signal processing unit, a signal outputting unit, and a signal comparison. The signal processing unit further comprises a first mode and a second mode.

The signal collecting unit receives a non-stationary signal with amplitude changes over time.

The signal processing unit is connected to the signal collecting unit, comprising a first mode and a second mode, the first mode decomposes the non-stationary signal by an ensemble empirical mode decomposition into a plurality of intrinsic mode functions, wherein each of the IMFs is an expression of one banded frequency component in the non-stationary signal, and each banded frequency component corresponds to one of the IMFs; then the second mode decomposes a first IMF with a region of interest by the EEMD into a plurality of envelop functions, wherein each of the envelop functions is an expression of one envelope frequency in the first IMF, and each envelope frequency corresponds to one of the envelop functions.

The phase function processing unit is connected to the signal processing unit, selecting a first envelop function from the envelop functions, retrieving a phase function of the first envelop function, obtaining a plurality of first-IMF envelope cycle frequencies, wherein each first-IMF envelope cycle frequency corresponds to the variation between cycles of the first IMF.

The amplitude function processing unit is connected to the phase function processing unit, selecting a second IMF from the IMFs at the frequency higher than the first IMF, retrieving an amplitude function of the second IMFs, and obtaining a plurality of second-IMF cycle frequencies, wherein each second-IMF cycle frequency corresponds to the variation of the second IMF.

The system further comprises a signal comparison unit is connected to the signal processing unit, comparing the phase function with the amplitude function on a time domain to generate a scattering plot, wherein the scattering plot is based on the first-IMF envelope cycle frequencies corresponding to the second-IMF cycle frequencies, wherein the system repeats signal processing from the amplitude function processing unit to the signal comparison unit until generate the scattering plots by comparing the phase function of the first envelope IMF with the amplitude function of each another IMF at the frequency higher than the first IMF.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

FIG. 1 is a block diagram of a system of signal processing according to one embodiment of the invention.

FIG. 2 is a flowchart of exemplary steps of a method of signal processing for phase-amplitude coupling according to one embodiment of the invention.

FIG. 3 illustrates decomposing the non-stationary signal to a plurality of IMFs according to one embodiment of the invention.

FIG. 4 illustrates a phase function of the IMF according to one embodiment of the invention.

FIG. 5 illustrates an amplitude function of the IMF according to one embodiment of the invention.

FIG. 6 illustrates a comparing between the phase function and the amplitude function on a time domain according to one embodiment of the invention.

FIG. 7 illustrates a scattering plots arraying based on the comparing between the phase function and the amplitude function according to one embodiment of the invention.

FIG. 8 illustrates a frequency spectrum based on a sum of the scattering plots and a modulation index multiplication according to one embodiment of the invention.

FIG. 9 illustrates determining a relation point of the frequency spectrum related with the first-IMF cycle frequency corresponding to the second-IMF cycle frequency according to one embodiment of the invention.

FIG. 10 illustrates a table based on the sum of the scattering plots and a modulation index multiplication within relation points.

FIG. 11 is a flowchart of exemplary steps of a method of signal processing for amplitude-amplitude coupling according to another embodiment of the invention.

FIG. 12 illustrates decomposing the non-stationary signal to a plurality of IMFs according to another embodiment of the invention.

FIG. 13 illustrates decomposing an IMF of the non-stationary signal to a plurality of envelop functions according to another embodiment of the invention.

FIG. 14 illustrates a frequency spectrum based on a product of the numbers and a modulation function value according to another embodiment of the invention.

FIG. 15 illustrates determining the relation point of the frequency spectrum related with the first-IMF cycle frequency corresponding to the second-IMF cycle frequency according to another embodiment of the invention.

FIG. 16 illustrates retrieving a plurality of phase bin centers from the phase function and a plurality of mean amplitudes from the amplitude function.

FIG. 17 illustrates a phase-amplitude plot related to phase bin centers and mean amplitudes.

FIG. 18 illustrates a modulation index in assessing different cases of the non-stationary signal.

FIG. 19 illustrates a color frequency spectrum based on the relative values of the present invention disclosure.

FIG. 20 illustrates a color frequency spectrum based on the relative values according to another embodiment of the invention.

### DETAILED DESCRIPTION OF THE INVENTION

The present invention discloses method and system of signal processing for phase-amplitude coupling and amplitude-amplitude coupling. It is understood that the method provides merely an example of the many different types of functional arraignments that may be employed to implement the operation of the various components of a system of signal processing for phase-amplitude coupling and amplitude-amplitude coupling, a computer system connected to the system of signal processing for phase-amplitude, a multiprocessor computing device, and so forth. The execution steps of the present invention may include application specific software which may store in any portion or component of the memory including, for example, random access memory (RAM), read-only memory (ROM), hard drive, solid-state drive, magneto optical (MO), IC chip, USB flash drive, memory card, optical disc such as compact disc (CD) or digital versatile disc (DVD), floppy disk, magnetic tape, or other memory components.

For embodiments, the system comprises a display device, a processing unit, a memory, an input device and a storage medium. The input device used to provide data such as image, text or control signals to an information processing system such as a computer or other information appliance. In accordance with some embodiments, the storage medium such as, by way of example and without limitation, a hard drive, an optical device or a remote database server coupled to a network, and stores software programs. The memory typically is the process in which information is encoded, stored, and retrieved etc. The processing unit performs data calculations, data comparisons, and data copying. The display device is an output device that visually conveys text, graphics, and video information. Information shown on the display device is called soft copy because the information exists electronically and is displayed for a temporary period of time. Display devices include CRT monitors, LCD monitors and displays, gas plasma monitors, and televisions. In accordance with such embodiments of present invention, the software programs are stored in the memory and executed by the processing unit when the computer system executes the method of the signal processing for phase-amplitude coupling and amplitude-amplitude coupling. Finally, information provided by the processing unit, presented on the display device or stored in the storage medium.

Many recent studies of complex systems have focused on cross-frequency coupling (CFC) in which interactions occur between rhythms at different frequencies that are either within the same signals or in different signals. CFC is of particular interest in brain activities because they are indicative of information propagation across different brain regions for specific neurophysiologic function. There are many different measures/varieties of CFC. Traditional Fourier-based CFC analysis can be inadequate due to the following intrinsic properties of biological rhythms: Nonlinear waveform: The waveform of rhythms is non-sinusoidal; Non-stationary: The amplitude and period of rhythms are unstable; Nonlinear interactions: The interactions between rhythms can be Phase-amplitude coupling (PAC) and Amplitude-amplitude coupling (AAC).

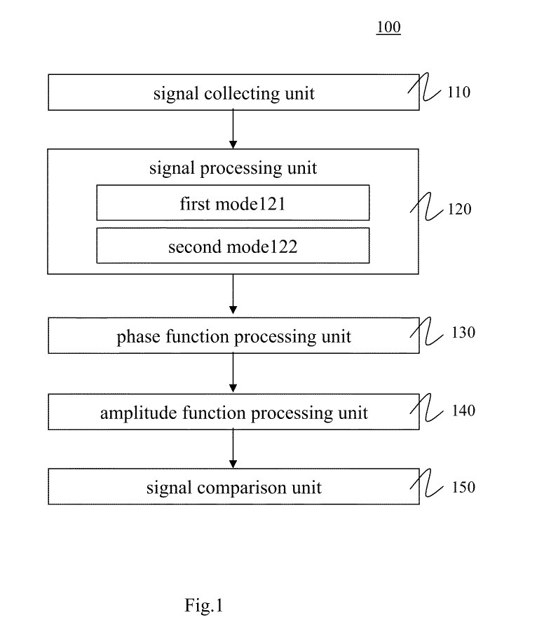

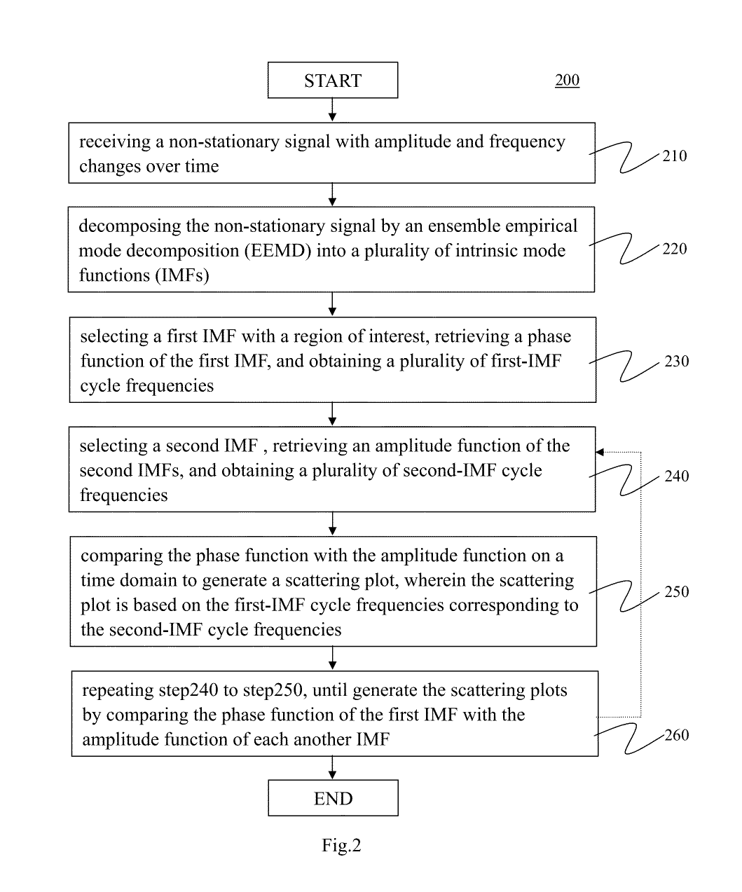

The present invention provides a method and system of signal processing for phase-amplitude coupling and amplitude-amplitude coupling. Please refer FIG. 1 and FIG. 2 respectively show a system 100 and a method of signal processing 200 for phase-amplitude coupling of the present invention. The method of the signal processing 200 may be implemented in the system 100. The system 100 comprises a signal collecting unit 110, a signal processing unit 120, a signal outputting unit 130, and a signal comparison 150. The signal processing unit 120 further comprises a first mode 121 and a second mode 122.

The signal collecting unit 110 is electrically connected to the signal processing unit 120. The signal processing unit 120 is electrically connected to the signal comparison unit 130. The signal outputting unit 130 is electrically connected to the amplitude function processing unit 140. Meanwhile, the amplitude function processing unit 140 is electrically connected to signal comparison 150.

It is understood that the flowchart of FIG. 2 provides merely an example of the many different types of functional arrangements that may be employed to implement the operation of the various components of the system 100 (FIG. 1). As an alternative, the flowchart of FIG. 2 may be viewed as depicting an example of steps of a method implemented in the system 100 according to one or more embodiments.

The method of the signal processing 200 for phase-amplitude coupling comprises the steps of: receiving a non-stationary signal with amplitude and frequency changes over time (step S210); the non-stationary signal is decomposed by an ensemble empirical mode decomposition (EEMD) into a plurality of intrinsic mode functions (IMFs), wherein each of the IMFs is an expression of one banded frequency component in the non-stationary signal, and each banded frequency component corresponds to one of the IMFs (step S220); then, a first IMF with a region of interest is selected, retrieves a phase function of the first IMF, and obtains a plurality of first-IMF cycle frequencies, wherein each first-IMF cycle frequency corresponds to the increment of the phase function across the cycle (step S230); a second IMF is selected, retrieves an amplitude function of the second IMFs, and obtains a plurality of second-IMF cycle frequencies, wherein each second-IMF cycle frequency corresponds to the variation of the second IMF (step S240); and the phase function is compared with the amplitude function on a time domain to generate a scattering plot, wherein the scattering plot is based on the first-IMF cycle frequencies corresponding to the second-IMF cycle frequencies. The method further comprises repeating step S230 to step S240, until generate the scattering plots by comparing the phase function of the first IMF with the amplitude function of each another IMF (step S260).

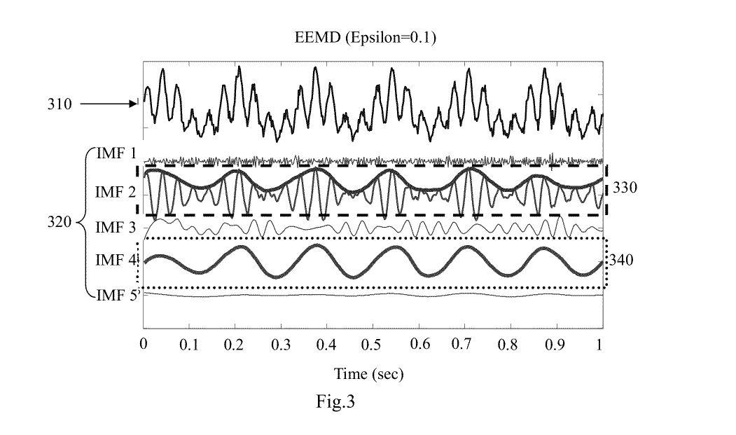

Reference is made to FIG. 3, FIG. 3 decomposing the non-stationary signal to a plurality of IMFs according to one embodiment of the invention. The signal collecting unit 110 (FIG. 1) receives a non-stationary signal 310 with amplitude and frequency changes over time. In another embodiment, the signal collecting unit 100 may receive the non-stationary signal 310 wirelessly.

In one embodiment, the non-stationary signal 310 is decomposed by the EEMD into a plurality of IMFs 320 in FIG. 3 by the signal processing unit 120 connected to the signal collecting unit 110. Preferably, the plurality of IMFs 320 with different equivalent. Each of the IMF is an expression of one banded frequency component in the non-stationary signal, and each banded frequency component corresponds to one of the IMFs.

For some embodiments, the signal processing unit 120 (FIG. 1) determines the plurality of IMFs 320 whether comprises a visual stationary frequency, wherein the stationary frequency is the visual stationary frequency. The signal processing unit 120 (FIG. 1) will process further steps after at least one of the plurality of IMFs 320 comprises the visual stationary frequency is determined.

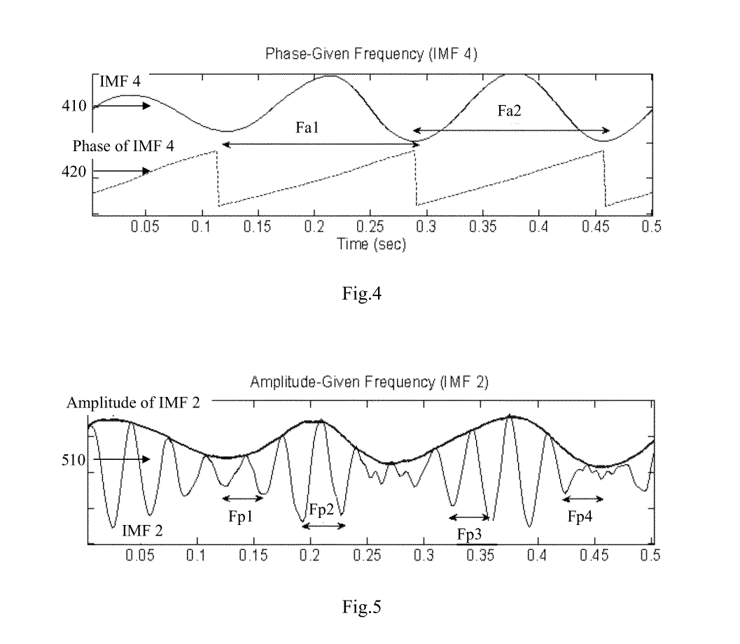

Please refer FIG. 3 and FIG. 4, FIG. 4 illustrates a phase function of the IMF according to one embodiment of the invention. The first IMF is a phase-given frequency (IMF4). The phase function processing unit 130 (FIG. 1) is connected to the signal processing unit 120 to select a first IMF 340 [symbol] 410, for example, IMF4 with a region of interest from the plurality of IMFs 320. The phase function processing unit 130 retrieves a phase function of the first IMF 340 [symbol] 410, and obtains a plurality of first cycle frequencies. In FIG. 4 illustrates the first IMF 340 [symbol] 410 and the phase of the IMF 420. Then, the phase function processing unit 130 (FIG. 1) retrieves a phase function, and obtain a plurality first-IMF cycle frequencies (e.g., Fa1 and Fa2). Each first-IMF cycle frequency (e.g., Fa1 and Fa2) corresponds to the increment of the phase function across the cycle.

Please refer FIG. 3 and FIG. 5, FIG. 5 illustrates an amplitude function of the IMF according to one embodiment of the invention. The second IMF is an amplitude-given frequency (IMF2). The amplitude function processing unit 140 (FIG. 1) is connected to the phase function processing unit 130 to select a second IMF 330 [symbol] 510, for example, IMF2. Then, the amplitude function processing unit 140 (FIG. 1) retrieves an amplitude function of the second IMFs and obtain a plurality of second-IMF frequencies (e.g., Fp1 [symbol] Fp2 [symbol] Fp3 and Fp4). Each second-IMF cycle frequency (e.g., Fp1 [symbol] Fp2 [symbol] Fp3 and Fp4) corresponds to the variation the second IMF.

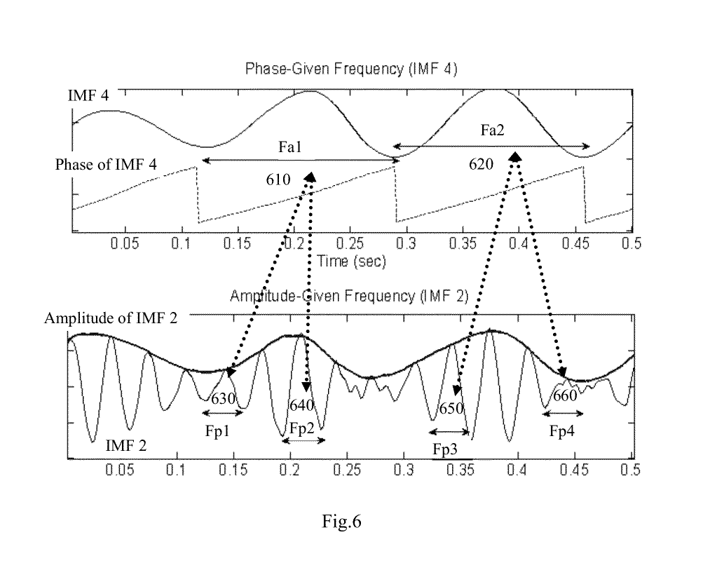

Please refer to FIG. 6, the signal comparison unit 150 compares the phase function with the amplitude function on the time domain based on the first-IMF cycle frequencies corresponding to the second-IMF cycle frequencies on the time domain. The phase-given frequency (IMF4) comprises a plurality of first-IMF cycle frequencies, for example, Fa1 610 and Fa2 620, wherein each first-IMF cycle frequency (Fa1 610 and Fa2 620) corresponds to the increment of the phase function across the cycle. The amplitude-given frequency (IMF2) comprises a plurality of second-IMF cycle frequencies, for example, Fp1 630 [symbol] the Fp2 640 [symbol] the Fp3 650 and the Fp4 660 according to the variation of the second IMF. The signal comparison unit 150 compares the phase function with the amplitude function on a time domain to generate a scattering plot based on the first-IMF cycle frequencies (Fa1 610 and Fa2 620) corresponding to the second-IMF cycle frequencies (Fp1 630 [symbol] the Fp2 640 [symbol] the Fp3 650 and the Fp4 660). As shown in FIG. 6, the first-IMF cycle frequency Fa1 610 corresponds to the second-IMF cycle frequency Fp1 630 and Fp2 640 on a time domain. The first-IMF cycle frequency Fa2 620 corresponds to second-IMF cycle frequency Fp3 650 and Fp4 660 on a time domain.

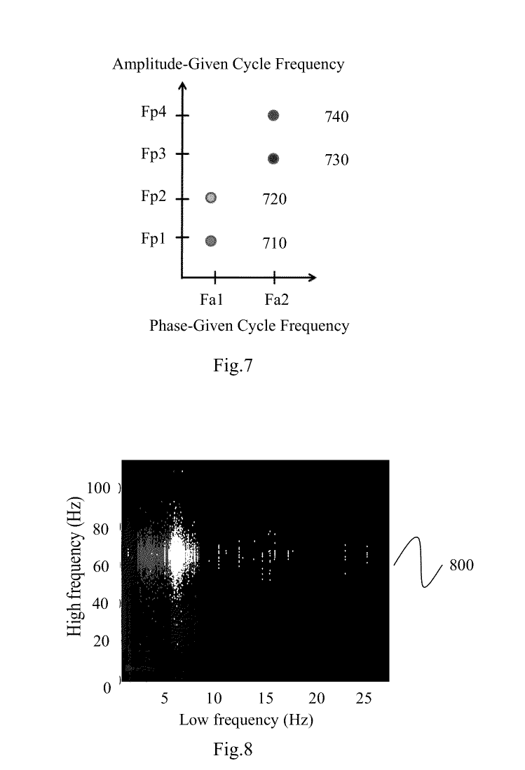

Please refer FIG. 7, FIG. 7 illustrates a scattering plots arraying based on comparing the phase function and the phase function according to one embodiment of the invention. The system 100 repeats the method of the signal processing 200 for selecting a second IMF from the IMFs at the frequency higher than the first IMF (step S240) to comparing the phase function with the amplitude function on a time domain (step S250), until generate the scattering plots by comparing the phase function of the first IMF with the amplitude function of each another IMF.

As shown in FIG. 7, the scattering plot comprises the first relation point 710, the second relation point 720, the third relation point 730 and the forth relation point 740. The first-IMF cycle frequency is a Phase-Given Frequency. The second-IMF cycle frequency is an Amplitude-Given Frequency. The relation point is represented by a coordinate according to the Phase-Given Frequency corresponding to the Amplitude-Given Frequency on a time domain.

The first pixel 710 is compared by the phase function of the first-IMF cycle frequency Fa1 610 with the amplitude function of the second-IMF cycle frequency Fp1 630 on a time domain, for example, (Fa1, Fp1). The second relation point 720 is compared by the phase function of the first-IMF cycle frequency Fa1 610 and the amplitude function of the second-IMF cycle frequency Fp2 640 on a time domain, for example, (Fa1, Fp2). The third relation point 730 is compared by the phase function of the first-IMF cycle frequency Fa2 620 and the amplitude function of the second-IMF cycle frequency Fp3 650 on a time domain, for example, (Fa2, Fp3). The forth relation point 740 is compared by the phase function of the first-IMF cycle frequency Fa2 620 and the amplitude function of the second-IMF cycle frequency Fp4 660 on a time domain, for example, (Fa2, Fp4). The signal comparison unit 150 further repeatedly compares the phase function of the first-IMF cycle frequency with the amplitude function of each another IMF to generate the scattering plots.

The signal comparison unit 150 (FIG. 1) compares the phase function with the amplitude function on a time domain to generate a scattering plot, wherein the scattering plot is based on the first-IMF cycle frequencies corresponding to the second-IMF cycle frequencies, further retrieves a plurality of phase bin centers from the phase function and a plurality of mean amplitudes from the amplitude function to generate a phase-amplitude distribution, calculating a Shannon entropy based on the mean amplitude corresponding to the phase bin center in the phase-amplitude distribution. The signal comparison unit 150 (FIG. 1) calculates a Shannon entropy based on the mean amplitude (0−2π) corresponding to the phase bin center in the scattering plot. The Shannon entropy is calculated using formula

$$H ( P ) = - {\sum }_{j = 1}^{N} P ( j ) log [ P ( j ) ]$$

wherein N is the number of phase bin center.

Furthermore, the signal comparison unit 150 (FIG. 1) calculates a Kullback-Leibler (KL) distance by subtracting the Shannon entropy from a maximum Shannon entropy. In fact, the KL distance is related to the Shannon entropy by the following formula

D_{KL}(P,U)=log(N)−H(P)

where (log (N) is the maximum Shannon entropy.

Therefore because H(P)≦log (N). The signal comparison unit 150 defines a modulation index for a distribution index of the non-stationary signal based on dividing the KL distance from the maximum Shannon entropy. The modulation index is calculated using formula

$$MI = \frac{{D}_{KL} ( P , U )}{log ( N )}$$

Please refer FIG. 8, FIG. 8 illustrates a frequency spectrum based on a sum of the scattering plots and a modulation index multiplication according to one embodiment of the invention. The signal comparison unit 150 repeatedly compares the phase function of the first-IMF cycle frequency with the amplitude function of each another IMF to generate the scattering plots. The system 100 further multiply the scattering plots by the modulation index from same IMFs to generate a plurality of relation points, summing the relation points on same time domain between different IMFs, and arraying the sum of the relation points to generate the frequency spectrum 800 based on the first-IMF cycle frequency corresponding to the second-IMF cycle frequency in a time interval, wherein the sum of the relation points is represented by different color ranges for quantities.

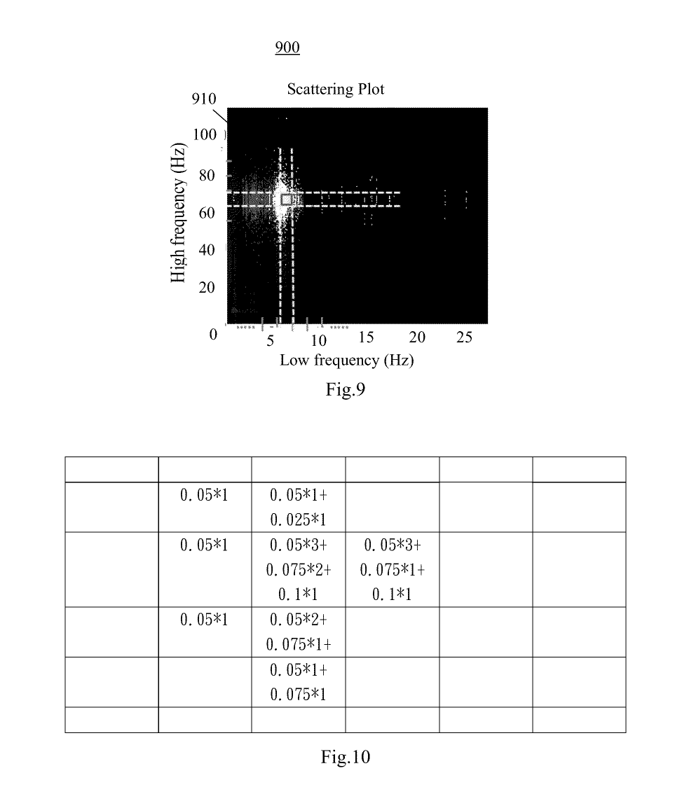

Please refer FIG. 9, FIG. 9 illustrates determining a relation point of the frequency spectrum related with the first-IMF cycle frequency corresponding to the second-IMF cycle frequency according to one embodiment of the invention. A relation point 910 of the frequency spectrum 900 is determined based on the first-IMF cycle frequency and the second-IMF cycle frequency on a time domain. The relation point is represented by a coordinate according to a low frequency corresponding to a high frequency on a time domain, for example (the low frequency, the high frequency).

The relation point is represented by a frequency coordinate according to the first-IMF cycle frequency corresponding to the second cycle frequency on a time domain. For example, the relation point is represented by the first-IMF cycle frequency and the second-IMF cycle frequency such as a frequency coordinate (7, 65) when the first cycle frequency is 7 s−1, the second cycle frequency is 65 s−1 during 0.2 s˜0.23 s.

FIG. 10 illustrates a table based on the sum of the scattering plots and a modulation index multiplication within relation points. As shown in FIG. 10, the system 100 further multiply the scattering plots by the modulation index from same IMFs (e.g., 0.05*1, 0.05*2, 0.05*3, 0.025*1, 0.075*1, 0.1*1) to generate a plurality of relation points, summing the relation points on same time domain between different IMFs (e.g., 0.05*1+0.025*1), and arraying the sum of the relation points to generate the frequency spectrum 800 based on the table in FIG. 10. The frequency spectrum 800 is presented by a low frequency as horizontal axes corresponding to a high frequency as vertical axes according to relation points.

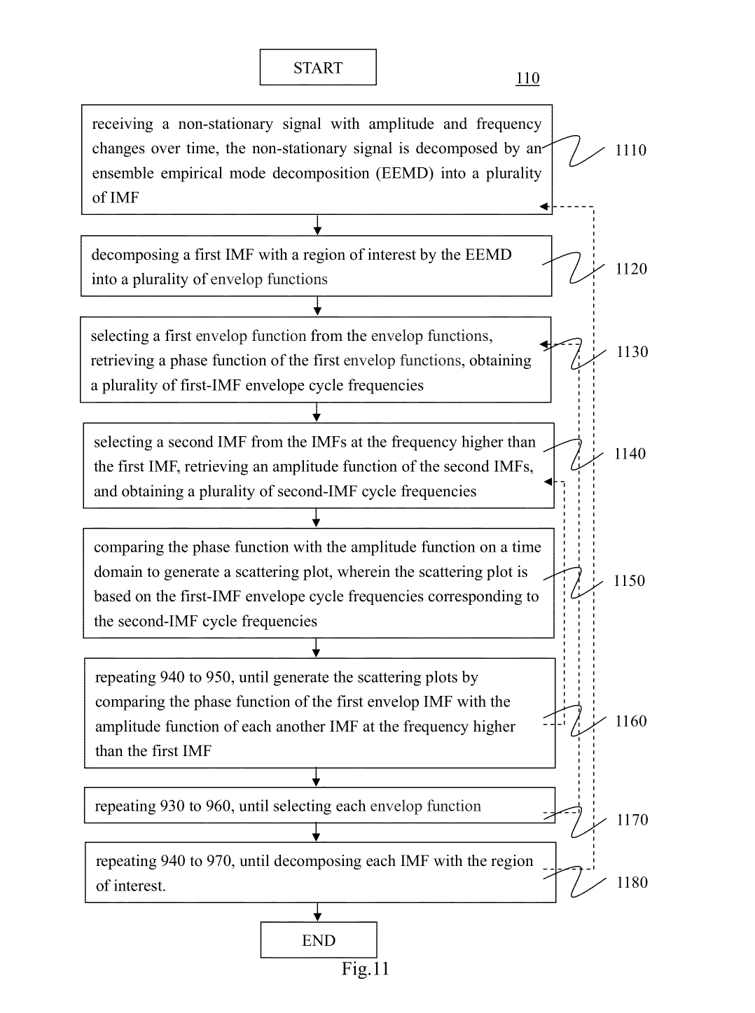

In another embodiment, the method of the signal processing 1100 and the system 100 can be applied on a mobile phone, a notebook, or a computer, which is not limited herein. It is understood that the flowchart 1100 of FIG. 11 provides merely an example of the many different types of functional arrangements that may be employed to implement the operation of the various components of the system 100 (FIG. 1). As an alternative, the flowchart of FIG. 11 may be viewed as depicting an example of steps of a method implemented in the system 100 according to one or more embodiments.

Please refer FIG. 11, FIG. 11 is a flowchart of exemplary steps of a method of signal processing for amplitude-amplitude coupling according to another embodiment of the invention. The method of the signal processing 1100 for amplitude-amplitude coupling comprises the steps of: a non-stationary signal with amplitude and frequency changes is received over time; the non-stationary signal is decomposed by an ensemble empirical mode decomposition (EEMD) into a plurality of intrinsic mode functions (IMFs), wherein each of the IMFs is an expression of one banded frequency component in the non-stationary signal, and each banded frequency component corresponds to one of the IMFs (step S1110);

Furthermore, a first IMF with a region of interest is decomposed by the EEMD into a plurality of envelop functions, wherein each envelop function is an expression of one envelope frequency in the first IMF, and each envelope frequency corresponds to one of the envelop functions (step S1120);

Then, a first envelop function is selected from the envelop functions, retrieving a phase function of the first envelop function, obtaining a plurality of first-IMF envelope cycle frequencies, wherein each first-IMF envelope cycle frequency corresponds to the variation between cycles of the first IMF (step S1130); a second IMF is selected from the IMFs at the frequency higher than the first IMF, retrieving an amplitude function of the second IMFs, and obtaining a plurality of second-IMF cycle frequencies, wherein each second-IMF cycle frequency corresponds to the variation of the second IMF (step S1140); the phase function is compared with the amplitude function on a time domain to generate a scattering plot, wherein the scattering plot is based on the first-IMF envelope cycle frequencies corresponding to the second-IMF cycle frequencies (step S1150). Then, repeating S1140 to S1150, until generate the scattering plots by comparing the phase function of the first envelop function with the amplitude function of each another IMF at the frequency higher than the first IMF (step S1160); repeating S1130 to S1160, until selecting each envelop function (step S1170). Finally, repeating 1120 to 1170, until decomposing each IMF with region of interest (step S1180).

The method of the signal processing 1100 for amplitude-amplitude coupling further comprises the step of repeating step S1130 to step S1160, until selecting each envelop function. The method of the signal processing 1100 for amplitude-amplitude coupling further comprises the step of repeating step S1120 to select each envelope IMF, until decomposing each IMF with the region of interest.

The of signal processing for Phase-Amplitude Coupling and Amplitude-Amplitude coupling performs Ensemble EMD on an ensemble of 100 signals with added white noise having variance 0.1 to avoid the mode mixing problem. The analytic form is shown as x(t)=Σⱼ₌₁ⁿcⱼ+rₙ and cⱼ(t)=aⱼ(t)e^{iθ}^{ⱼ}^{(t)}, where x(t) is the input signal, cj, aj and θj correspond to the jth IMF with its amplitude and phase modulation separately, while rn stands for the residue of x(t). To ensure in having a complete and orthogonal basis and avoid the mode flipping phenomena, an index of orthogonality for any pair of components is defined as

$${IO}_{i , j} = \frac{{Σ}_{t} {c}_{i} ( t ) \cdot {c}_{j} ( t )}{\vert {c}_{i} ( t ) \vert \vert {c}_{j} ( t ) \vert} ,$$

The adjacent pair of components are merged into one component while the index exceeds 0.1 for the synthetic signals, and use 0.3 for the brain signals. For the jth mode denoted as cjx, we obtained the instantaneous amplitude aj(t) and phase θj(t) using the Hilbert transform given by

$${c}_{jy} ( t ) = {\int }_{τ} \frac{{c}_{jx} ( τ )}{t - τ} d τ , z ( t ) = {c}_{jx} ( τ ) + {ic}_{jy} ( t ) = {a}_{i} ( t ) {e}^{i {θ}_{j} ( t )}$$

$${a}_{i} ( t ) = \sqrt{{{c}_{jx} ( τ )}^{2} + {{c}_{jy} ( t )}^{2}} and {θ}_{j} ( t ) = {tan}^{- 1} \frac{{c}_{jy} ( t )}{{c}_{jx} ( t )}$$

The phase is unwound in a way that prioritizes monotonicity denoted as φ. In addition to computing the amplitude and phase time series for each mode, a frequency time series Fj(t) is calculated. A frequency is calculated for each oscillatory cycle, where cycles are defined, somewhat arbitrarily, to span the time points within the intervals (2πk, 2π+2πk]. The frequency of the cycle starting at time point s and ending at time point t was defined to be

$$F ( s , t ) = ( \frac{1}{t - s} ) ( \frac{ϕ ( t ) - ϕ ( s )}{2 π} ) Hz , {F}_{j} ( u ) = f ( s , t ) , s < u < t$$

The amplitude modulation, or the envelope function, will confront with the difficulty in finding its phase modulation. Since the envelope function rides the wave over the baseline, it will lead to an invalid result in using the Hilbert Transform. The envelope function possesses a factorization in C into irreducible and relatively prime polynomials with certain multiplicities. Instead of using the Fourier-based decomposition process, the reduced envelope function can be found adaptively and sparsely via suitable 2nd Ensemble EMD computations. Consider IMFs ck, k=1, . . . n of the envelope function aj(t) with rm stands for its residue. The reduced envelope function is given by aⱼ(t)=Σₖ₌₁ⁿcₖ+rₘ. After applying the 2nd Hilbert transform on IMFs ck, the evaluation of the phase modulation over the envelope is therefore being a reality.

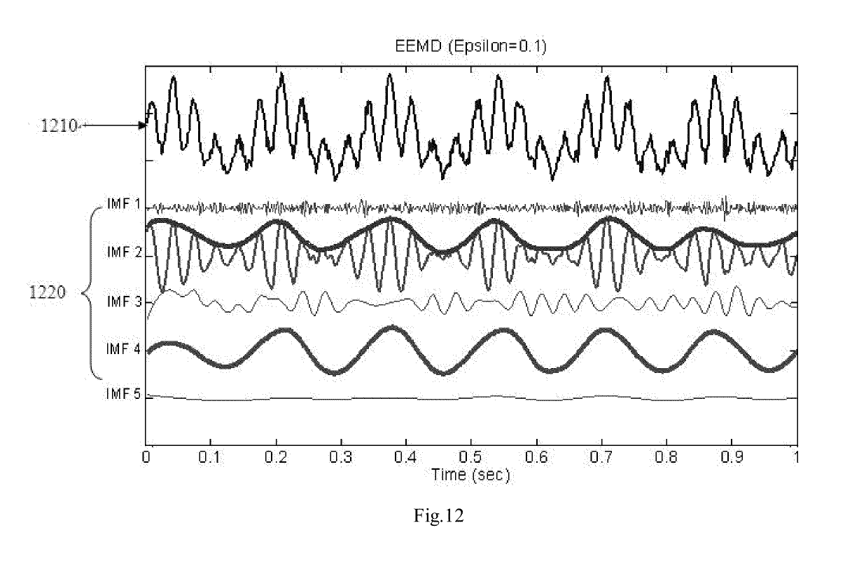

FIG. 12 illustrates decomposing the non-stationary signal to a plurality of IMFs according to another embodiment of the invention. Firstly, the signal collecting unit 110 receives a non-stationary signal 1210 with amplitude and frequency changes over time. In another embodiment, the signal collecting unit 100 (FIG. 1) may receive the non-stationary signal 1210 wirelessly. In one embodiment, the non-stationary signal 1210 is decomposed by the EEMD into plurality of intrinsic mode functions (IMFs) 1220 including IMF1 [symbol] IMF2 [symbol] IMF3 [symbol] IMF4 and IMF5 in FIG. 12. Preferably, the signal processing unit 120 is connected to the signal collecting unit 110, comprising a first mode 121 and a second mode 122, the first mode 121 decomposes the non-stationary signal by an ensemble empirical mode decomposition (EEMD) into the plurality of intrinsic mode functions 1220, wherein each of the IMFs is an expression of one banded frequency component in the non-stationary signal, and each banded frequency component corresponds to one of the IMFs.

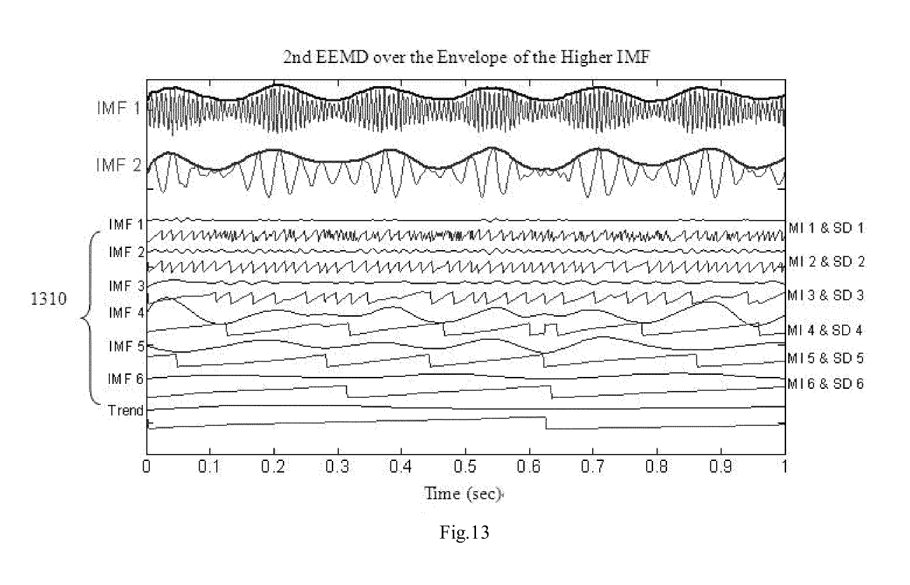

FIG. 13 illustrates decomposing an IMF of the non-stationary signal to a plurality of envelope functions according to another embodiment of the invention. As shown in FIG. 13, the second mode 122 (FIG. 1) decomposes a first IMF with a region of interest by the EEMD into a plurality of envelope functions 1310, wherein each of the envelope functions is an expression of one envelope frequency in the first IMF, and each envelope frequency corresponds to one of the envelope functions.

A phase function processing unit 130 is connected to the signal processing unit 120 for selecting a first envelope function from the envelope functions 1310 and retrieving a phase function of the first envelope function to obtain a plurality of first-IMF envelope cycle frequencies, wherein each first-IMF envelope cycle frequency corresponds to the increment of the phase function across the cycle.

An amplitude function processing unit 140 is connected to the phase function processing unit 130 for selecting a second IMF from the IMFs 1220 with at the frequency higher than the first IMF, retrieving an amplitude function of the second IMFs, and obtaining a plurality of second-IMF cycle frequencies, wherein each second-IMF cycle frequency corresponds to the variation of the second IMF.

A signal comparison unit 150 is connected to the signal processing unit 140, comparing the phase function with the amplitude function on a time domain to generate a scattering plot, wherein the scattering plot is based on the first-IMF envelope cycle frequencies corresponding to the second-IMF cycle frequencies.

The system 100 further repeats the method of the signal processing 1100 from the amplitude function processing unit 140 to the signal comparison unit 150 until generate the scattering plots by comparing the phase function of the first-IMF envelope IMF with the amplitude function of each another IMF at the frequency higher than the first IMF.

The system 100 further repeats the method of the signal processing 1100 from the second mode 122 of the signal processing unit 120 to the signal comparison unit 150 until selecting each envelope function.

The system 100 further repeats the method of the signal processing 1100 from the first mode of the signal processing unit 120 to the signal comparison unit 150 until decomposing each IMF with the region of interest.

As discussed earlier, the signal processing unit 120 retrieves a plurality of phase bin centers from the phase function and a plurality of mean amplitudes from the amplitude function to generate a phase-amplitude distribution, calculating a Shannon entropy based on the mean amplitude corresponding to the phase bin center in the phase-amplitude distribution.

The signal processing unit 120 calculates a Kullback-Leibler distance by subtracting the Shannon entropy of the phase-amplitude distribution from a maximum Shannon entropy, calculating a modulation index for a distribution index of the non-stationary signal based on dividing the Kullback-Leibler distance from the maximum Shannon entropy.

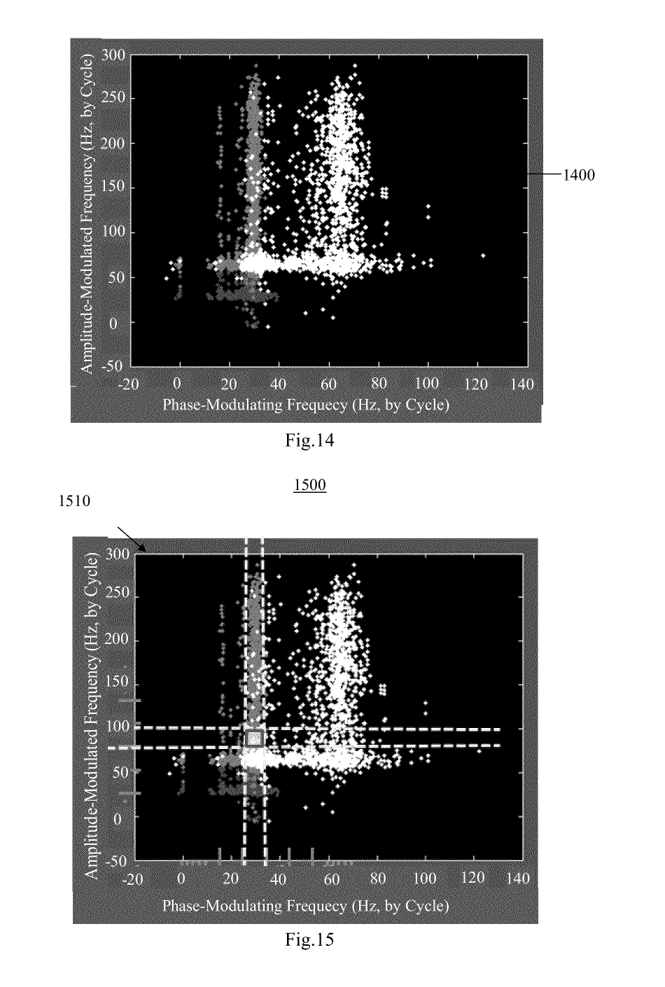

FIG. 14 illustrates a frequency spectrum based on a product of the numbers and a modulation function value according to another embodiment of the invention. With further reference to FIG. 14, after the scattering plots is generated by comparing the phase function of the first envelop function with the amplitude function of each another IMF at the frequency higher than the first IMF. The system 100 retrieve a number by summing the scattering plots on same time domain between different envelop functions and IMF; then multiply each of the numbers by a modulation function value to generate a plurality of relation points; and array the sum of the relation points to generate a frequency spectrum based on the first-IMF envelope cycle frequency corresponding to the second-IMF cycle frequency in a time interval ∘

the modulation function value is calculated by dividing sum of product of the modulation indexes and a plurality of standard deviations from each envelop function by sum of the standard deviations. The modulation function value defined as

modulation function value=Σᵢ(MIᵢ×SDᵢ)/ΣᵢSDᵢ

FIG. 15 illustrates determining the relation point of the frequency spectrum related with the first-IMF cycle frequency corresponding to the second-IMF cycle frequency according to another embodiment of the invention. A relation point 1510 in the frequency spectrum 1500 determined based on the first-IMF cycle frequency and the second cycle frequency on a time domain. The frequency spectrum 1500 provides a phase-modulating frequency as horizontal axes corresponding to an amplitude-modulating frequency as vertical axes to determine relation points. The relation point is represented by a coordinate based on the first envelope cycle frequencies corresponding to the second cycle frequencies

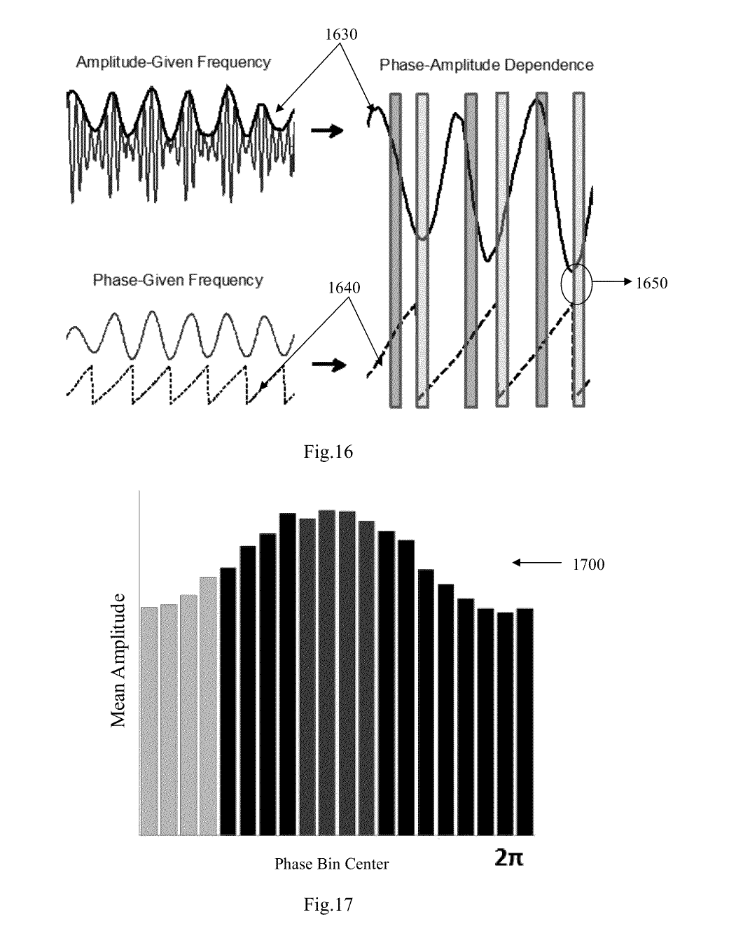

FIG. 16 illustrates retrieving a plurality of phase bin centers from the phase function and a plurality of mean amplitudes from the amplitude function. FIG. 17 illustrates a phase-amplitude plot related to phase bin centers and mean amplitudes. The phase function processing unit 130 retrieves the phase function of the phase-given frequency 1640, and obtains a plurality of first-IMF cycle frequencies, wherein each first-IMF cycle frequency corresponds to the variation between cycles of the phase function. The amplitude function processing unit 1630 retrieves the amplitude function of the amplitude-given frequency, obtains a plurality of second-IMF cycle frequencies according to the variation between of the amplitude function. The system 100 (FIG. 1) further retrieves a plurality of phase bin centers 1650 from the phase function and a plurality of mean amplitudes from the amplitude function to generate a phase-amplitude distribution. The system is based on phase bin centers 1650 and mean amplitudes to generate a phase-amplitude plot 1700.

The Shannon entropy based inverse entropy measure, as it is flexible and sensitive to both the form and the degree of dependence of amplitude on phase. A phase-amplitude “distribution” is constructed first in order to compute the inverse entropy measure, after dividing the phase domain (0, 2π] into N bins (N=20 in our study), the high-frequency amplitudes are binned according to the low-frequency phase. Summing these amplitudes within each bin, and dividing by the total high-frequency amplitude yields the proportion of the high-frequency amplitude occurring within each phase bin. The Shannon entropy H of the distribution P of amplitude by phase is then computed using the equation

H(P)=−Σⱼ₌₁^{N}P(j)log [P(j)],

subtracted from the maximum possible entropy log (N) in the uniform distribution U, the Kullback-Leibler (KL) distance is defined as

D_{KL}(P,U)=log(N)−H(P)

then divided the KL distance by the maximum possible entropy, yielding a quantity between zero and one, called the modulation index (MI).

An index of one is obtained when all the amplitude occurs in a single phase bin, namely the Bernoulli distribution 1280, and a value of zero is evaluated in the uniform distribution on the contrary. To quantify the amplitude to amplitude modulation for each IMFs pair, the system 100 handles the IMFs pairs (IMFi & IMFj, i>j) as described below. First, IMFs with higher frequency (IMFj): According to the cycle by cycle frequency of IMFj, the system 100 first builds the histogram of IMFj showing frequency distribution into four bins with equal frequency binning (IMFjm); for every quarter of frequency binning, the samples within as Binjm, with their number of sample represented as njm, where m=1, 2, 3 and 4. Note that this part can be eliminated, especially in the case with no sufficient sample points. Second, IMFs with lower frequency (IMFi): the system 100 applies the 2nd Ensemble EMD on the amplitude modulation of an IMFi with its trend being taken off. The IMFs decomposed from the amplitude modulation of IMFi as IMFik, where k<log (n) and n stands for the number of sample points. The system 100 further evaluates the standard deviation (SD) of the specific parts of oscillation in IMFik according to the Binjm aligned, denoted as SDijmk. For each IMFik, the phase modulation can be found after the Hilbert transform is applied.

After evaluating the modulation index, represented as MIijmk, of the envelope of IMFj within Binjm on the phases of Binjm aligned IMFik, the amplitude to amplitude modulation index between IMFi within Binjm and IMFjm can therefore be given by

$${MI}_{ijm} = \frac{{Σ}_{k} ( {MI}_{ijmk} \times {SD}_{ijmk} )}{{Σ}_{k} {SD}_{ijmk}}$$

While the amplitudes modulation of IMFj on the phases of IMFi's envelope can be equated as

$${MI}_{ij} = \frac{{Σ}_{m} ( {MI}_{ijm} \times {n}_{jm} )}{{Σ}_{m} {n}_{jm}}$$

The modulation index of each IMF on all its higher-frequency IMFs is therefore calculated. In other words, we calculate the MI of the phase of IMF n on the amplitude of IMFs n−1, n−2, . . . , 2, and 1. We ignore the effects of the phase of IMF p on IMF q, when p<q.

In the time-domain spirit of Ensemble EMD, after identifying the cycle blocks of each IMF, the system 100 shuffles the blocks of the amplitude-given and phase-given time series corresponding to these cycles. The system 100 performs enough shuffles to guarantee a random permutation of the cycles for φi from IMFi and Aj from IMFj separately, and then calculate the MI of the shuffled φi from IMFi on the shuffled Aj from IMFj in which φi and Aj stand for the phase and amplitude modulation separately. For example, the system 100 performs 100 times, obtaining an empirical distribution of MI for the given pair of phase-giving and amplitude-giving IMFs. The system 100 uses the mean and standard deviation of this distribution to z-score the observed MI, and then threshold these z-scores using a standard normal distribution, ignoring those which do not exceed a significance level of p=0.05 (Bonferroni-corrected over all pairs of phase-giving and amplitude-giving IMFs). As EEMD yields a complete decomposition, it is possible to define a “total thresholded MI” over all pairs of phase-giving and amplitude-giving modes—or, alternatively, over the entire phase frequency-amplitude frequency plane.

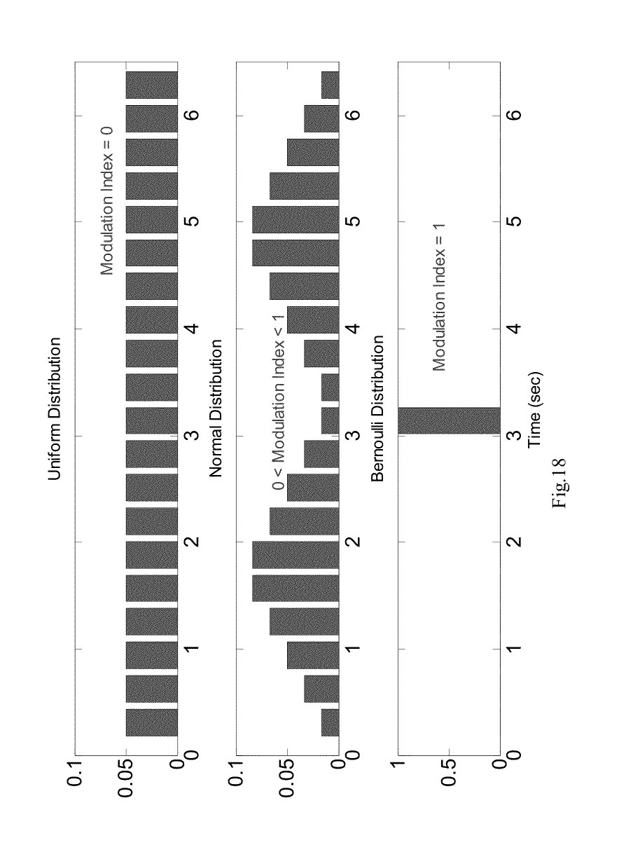

FIG. 18 illustrates a modulation index in assessing different cases of the non-stationary signal. As shown in FIG. 18, the modulation index in assessing different cases of the no-stationary signal. The modulation index has three different cases in the no-stationary signal. The modulation index value of 0 happens if the no-stationary signal is a uniform distribution 1800, The modulation index value between 0 and 1 happens if the no-stationary signal is normal distribution 1810, and The modulation index value of 1 happens if the no-stationary signal is Bernoulli distribution 1820.

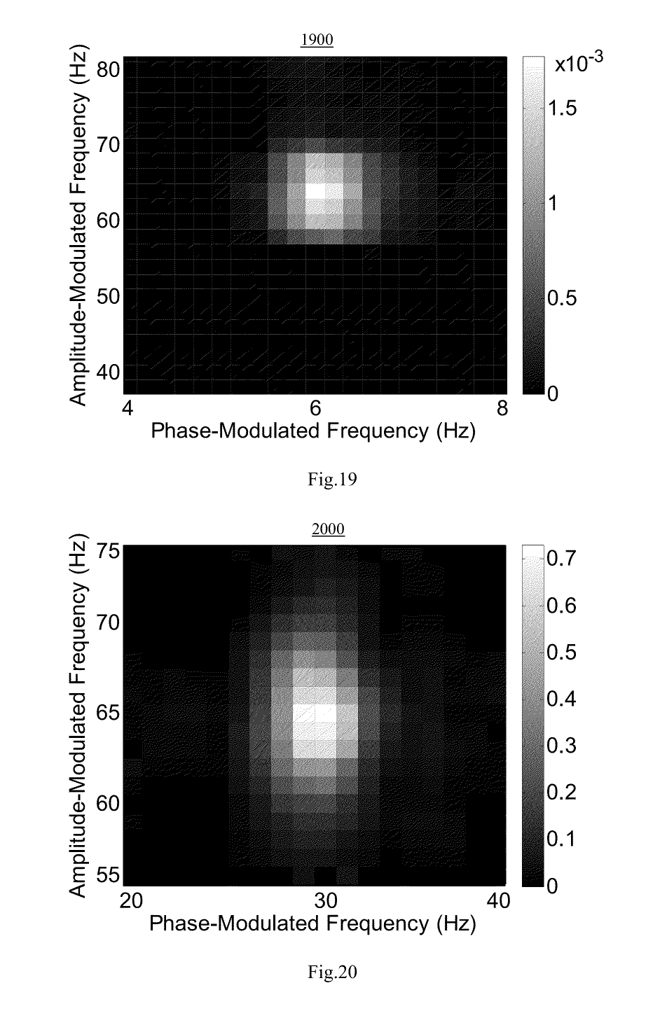

FIG. 19 illustrates a color frequency spectrum based on the relative values of the present invention disclosure. FIG. 20 illustrates a color frequency spectrum based on the relative values according to another embodiment of the invention. The sum of the relation points is represented by different color ranges for quantities

As shown in FIG. 19, a color frequency spectrum 1900 is generated based on relative values from the plurality IMFs with a visual stationary frequency. As shown in FIG. 20, a color frequency spectrum 2100 is generated by multiplying the scattering plots by the modulation index from same envelop functions and IMFs to generate a plurality of relation points, summing the relation points on same time domain between different envelop functions and IMFs, and arraying the sum of the relation points. The color frequency spectrum 1900 [symbol] 2000 had represented by different color ranges for quantities.

The method of signal processing for Phase-Amplitude Coupling and Amplitude-Amplitude coupling is provided to quantify the Phase-Amplitude Coupling and Amplitude-Amplitude coupling between nonstationary oscillations that are embedded in noisy, multiscale fluctuations. The invention of simulations is more reliable than the traditional Fourier-based approach, especially for nonlinear and nonstationary signals. The present invention analyzes electrocorticography (ECoG) signals that were recorded from patients during seizures with electrodes placed directly on the cortex. We found strong AAC between high β waves (20-30 Hz) or γ waves (30-100 Hz) and high-frequency oscillations (100-300 Hz) within the individual channels that are responsible for epileptogenesis. The present invention also found that the degree and characteristic frequency of AAC were changing at different seizure stages. Notably, such cross-frequency interactions in seizure EEGs could not be revealed by using traditional Fourier-based methods, which is likely impeded by intrinsic nonstationary features in ECoG signals as we demonstrated using simulations and surrogate data. These results support that the present invention serves as a useful tool to assess pathology of seizure dynamics and to explore dynamic controls in other complex physical and physiological systems.

What is claimed is:

1. A method of signal processing for phase-amplitude coupling, the method comprising:
step 1. receiving a non-stationary signal with amplitude and frequency changes over time;
step 2. decomposing the non-stationary signal by an ensemble empirical mode decomposition (EEMD) into a plurality of intrinsic mode functions (IMFs), wherein each of the IMFs is an expression of one banded frequency component in the non-stationary signal, and each banded frequency component corresponds to one of the IMFs;
step 3. selecting a first IMF with a region of interest, retrieving a phase function of the first IMF, and obtaining a plurality of first-IMF cycle frequencies, wherein each first-IMF cycle frequency corresponds to the increment of the phase function across the cycle;
step 4. selecting a second IMF, retrieving an amplitude function of the second IMFs, and obtaining a plurality of second-IMF cycle frequencies, wherein each second-IMF cycle frequency corresponds to the variation of the second IMF; and
step 5. comparing the phase function with the amplitude function on a time domain to generate a scattering plot, wherein the scattering plot is based on the first-IMF cycle frequencies corresponding to the second-IMF cycle frequencies;
Step 6. repeating step 4 to step 5, until generate the scattering plots by comparing the phase function of the first IMF with the amplitude function of each another IMF.

2. The method of claim 1, wherein step 5 further comprises:
retrieving a plurality of phase bin centers from the phase function and a plurality of mean amplitudes from the amplitude function to generate a phase-amplitude distribution, calculating a Shannon entropy based on the mean amplitude corresponding to the phase bin center in the phase-amplitude distribution; and
calculating a Kullback-Leibler distance by subtracting the Shannon entropy of the phase-amplitude distribution from a maximum Shannon entropy, calculating a modulation index for a distribution index of the non-stationary signal based on dividing the Kullback-Leibler distance from the maximum Shannon entropy.

3. The method of claim 2, wherein step 6 further comprising:
multiplying the scattering plots by the modulation index from same IMFs to generate a plurality of relation points, summing the relation points on same time domain between different IMFs, and arraying the sum of the relation points to generate a frequency spectrum based on the first-IMF cycle frequency corresponding to the second-IMF cycle frequency in a time interval.

4. The method of claim 3, wherein the sum of the relation points is represented by different color ranges for quantities.

5. The method of claim 1, wherein the first-IMF cycle frequency is a Phase-given frequency.

6. The method of claim 1, wherein the second-IMF cycle frequency is an Amplitude-Given Frequency.

7. A method of signal processing for amplitude-amplitude coupling, the method comprising:
step 1. receiving a non-stationary signal with amplitude and frequency changes over time;
step 2. decomposing the non-stationary signal by an ensemble empirical mode decomposition (EEMD) into a plurality of intrinsic mode functions (IMFs), wherein each of the IMFs is an expression of one banded frequency component in the non-stationary signal, and each banded frequency component corresponds to one of the IMFs;
step 3. decomposing a first IMF with a region of interest by the EEMD into a plurality of envelop functions, wherein each envelop function is an expression of one envelope frequency in the first IMF, and each envelope frequency corresponds to one of the envelop functions;
step 4. selecting a first envelop function from the envelop functions, retrieving a phase function of the first envelop function, and obtaining a plurality of first-IMF envelope cycle frequencies, wherein each first-IMF envelope cycle frequency corresponds to the variation between cycles of the first IMF;
step 5. selecting a second IMF from the IMFs at the frequency higher than the first IMF, retrieving an amplitude function of the second IMFs, and obtaining a plurality of second-IMF cycle frequencies, wherein each second-IMF cycle frequency corresponds to the variation of the second IMF; and
step 6. comparing the phase function with the amplitude function on a time domain to generate a scattering plot, wherein the scattering plot is based on the first-IMF envelope cycle frequencies corresponding to the second-IMF cycle frequencies.
step 7. repeating step 5 to step 6, until generate the scattering plots by comparing the phase function of the first envelop function with the amplitude function of each another IMF at the frequency higher than the first IMF.

8. The method of claim 7, further comprises step 8:
repeating step 4 to step 7, until selecting each envelop function.

9. The method of claim 8, further comprises step 9:
repeating step 3 to step 8, until decomposing each IMF with the region of interest.

10. The method of claim 7, wherein step 6 further comprises:
retrieving a plurality of phase bin centers from the phase function and a plurality of mean amplitudes from the amplitude function to generate a phase-amplitude distribution, calculating a Shannon entropy based on the mean amplitude corresponding to the phase bin center in the phase-amplitude distribution; and
calculating a Kullback-Leibler distance by subtracting the Shannon entropy of the phase-amplitude distribution from a maximum Shannon entropy, calculating a modulation index for a distribution index of the non-stationary signal based on dividing the Kullback-Leibler distance from the maximum Shannon entropy.

11. The method of claim 10, step 7 further comprising:
retrieving a number by summing the scattering plots on same time domain between different envelop functions and IMF;
multiplying each of the numbers by a modulation function value to generate a plurality of relation points; and
arraying the sum of the relation points to generate a frequency spectrum based on the first-IMF envelope cycle frequency corresponding to the second-IMF cycle frequency in a time interval;
the modulation function value is calculated by dividing sum of product of the modulation indexes and a plurality of standard deviations from each envelop function by sum of the standard deviations.

12. The method of claim 11, wherein the sum of the relation points is represented by different color ranges for quantities.

13. The method of claim 7, wherein the first-IMF cycle frequency is a Phasegiven frequency.

14. The method of claim 7, wherein the second-IMF cycle frequency is an Amplitude-Given Frequency

15. A system of signal processing for phase-amplitude coupling:
a signal collecting unit, receiving a non-stationary signal with amplitude and frequency changes over time;
a signal processing unit, connected to the signal collecting unit, decomposing the non-stationary signal by an ensemble empirical mode decomposition (EEMD) into a plurality of intrinsic mode functions (IMFs), wherein each of the IMFs is an expression of one banded frequency component in the non-stationary signal, and each banded frequency component corresponds to one of the IMFs;
a phase function processing unit, connected to the signal processing unit, selecting a first IMF with a region of interest, retrieving a phase function of the first IMF, and obtaining a plurality of first-IMF cycle frequencies, wherein each first-IMF cycle frequency corresponds to the increment of the phase function across the cycle;
an amplitude function processing unit, connected to the phase function processing unit, selecting a second IMF, retrieving an amplitude function of the second IMFs, and obtaining a plurality of second-IMF cycle frequencies according to the variation between of the second IMF; and
a signal comparison unit, connected to the amplitude function processing unit, comparing the phase function with the amplitude function on a time domain, generating a scattering plot according to the first-IMF cycle frequencies corresponding to the second-IMF cycle frequencies;
Wherein the system repeats signal processing from the amplitude function processing unit to signal comparison unit until generate the scattering plots by comparing the phase function of the first IMF with the amplitude function of each another IMF.

16. The system of claim 15, wherein the signal processing unit retrieves a plurality of phase bin centers from the phase function and a plurality of mean amplitudes from the amplitude function to generate a phase-amplitude distribution, calculating a Shannon entropy based on the mean amplitude corresponding to the phase bin center in the phase-amplitude distribution; and
calculating a Kullback-Leibler distance by subtracting the Shannon entropy of the phase-amplitude distribution from a maximum Shannon entropy, calculating a modulation index for a distribution index of the non-stationary signal based on dividing the Kullback-Leibler distance from the maximum Shannon entropy.

17. The system of claim 15, wherein the system further multiply the scattering plots by the modulation index from same IMFs to generate a plurality of relation points, summing the relation points on same time domain between different IMFs, and arraying the sum of the relation points to generate a frequency spectrum based on the first-IMF cycle frequency corresponding to the second-IMF cycle frequency in a time interval.

18. The system of claim 17, wherein the system determines the sum of the relation points had represented by different color ranges for quantities.

19. A system of signal processing for amplitude-amplitude coupling:
a signal collecting unit, receiving a non-stationary signal with amplitude and frequency changes over time;
a signal processing unit, connected to the signal collecting unit, comprising a first mode and a second mode, the first mode decomposes the non-stationary signal by an ensemble empirical mode decomposition (EEMD) into a plurality of intrinsic mode functions (IMFs), wherein each of the IMFs is an expression of one banded frequency component in the non-stationary signal, and each banded frequency component corresponds to one of the IMFs; then the second mode decomposes a first IMF with a region of interest by the EEMD into a plurality of envelop functions, wherein each of the envelop functions is an expression of one envelope frequency in the first IMF, and each envelope frequency corresponds to one of the envelop functions;
a phase function processing unit, connected to the signal processing unit, selecting a first envelop function from the envelop functions, retrieving a phase function of the first envelop function, obtaining a plurality of first-IMF envelope cycle frequencies, wherein each first-IMF envelope cycle frequency corresponds to the variation between cycles of the first IMF;
an amplitude function processing unit, connected to the phase function processing unit, selecting a second IMF from the IMFs at the frequency higher than the first IMF, retrieving an amplitude function of the second IMFs, and obtaining a plurality of second-IMF cycle frequencies, wherein each second-IMF cycle frequency corresponds to the variation of the second IMF; and
a signal comparison unit, connected to the signal processing unit, comparing the phase function with the amplitude function on a time domain to generate a scattering plot, wherein the scattering plot is based on the first-IMF envelope cycle frequencies corresponding to the second-IMF cycle frequencies.
Wherein the system repeats signal processing from the amplitude function processing unit to the signal comparison unit until generate the scattering plots by comparing the phase function of the first envelop function with the amplitude function of each another IMF at the frequency higher than the first IMF.

20. The system of claim 19, wherein the system further repeats signal processing from the second mode of the signal processing unit to the signal comparison unit until selecting each envelop function.

21. The system of claim 20, wherein the system further repeats signal processing from the first mode of the signal processing unit to the signal comparison unit until decomposing each IMF with the region of interest.

22. The system of claim 19, wherein the signal processing unit retrieves a plurality of phase bin centers from the phase function and a plurality of mean amplitudes from the amplitude function to generate a phase-amplitude distribution, calculating a Shannon entropy based on the mean amplitude corresponding to the phase bin center in the phase-amplitude distribution; and
calculating a Kullback-Leibler distance by subtracting the Shannon entropy of the phase-amplitude distribution from a maximum Shannon entropy, calculating a modulation index for a distribution index of the non-stationary signal based on dividing the Kullback-Leibler distance from the maximum Shannon entropy.

23. The system of claim 22, wherein the system further retrieve a number by summing the scattering plots on same time domain between different envelop functions and IMF; then multiply each of the numbers by a modulation function value to generate a plurality of relation points; and array the sum of the relation points to generate a frequency spectrum based on the first-IMF envelope cycle frequency corresponding to the second-IMF cycle frequency in a time interval; the modulation function value is calculated by dividing sum of product of the modulation indexes and a plurality of standard deviations from each envelop function by sum of the standard deviations.

24. The system of claim 23, wherein the signal comparison unit determines the sum of the relation points had represented by different color ranges for quantities.
